(19) United States
(12) Patent Application Publication
(10) Pub. No.: US 2022/0340153 A1
(43) Pub. Date: Oct. 27, 2022

(54) SIMULATED TEST CREATION

(71) Applicant: GM Cruise Holdings LLC, San Francisco, CA (US)

(72) Inventors: Casey Weaver, San Francisco, CA (US); Michael Sindelar, San Francisco, CA (US); Sidhant Gandhi, San Jose, CA (US); Di Gao, San Francisco, CA (US); Shu Xu, San Francisco, CA (US); Alka Pai, San Francisco, CA (US)

(21) Appl. No.: 17/237,282

(22) Filed: Apr. 22, 2021

(51) Int. Cl. B60W 50/06; G06K 9/00; G07C 5/00; G06F 30/20; B60W 40/06

(52) U.S. Cl. CPC B60W 50/06; G06K 9/00791; G07C 5/008; G06F 30/20; B60W 40/06; B60W 2420/52; B60W 2420/42; B60W 2554/4026; B60W 2554/4029

(57) ABSTRACT

The disclosed technology provides solutions for generating simulated scenes to facilitate autonomous vehicle (AV) testing. In some implementations, the disclosed technology encompasses methods for generating simulated scenes that can includes steps for receiving road data, wherein the road data comprises sensor data collected for a recorded scene measured using one or more vehicle-mounted sensors, processing the road data to generate semantic scene data, and generating a simulated scene based on the semantic scene data. Systems and machine-readable media are also provided.

### BACKGROUND

### 1. Technical Field

The subject technology relates to solutions for improving the operation of autonomous vehicles (AVs) and, for improving AV testing by generating simulated driving environments or simulated scenes using semantic data.

### 2.Introduction

Autonomous vehicles (AVs) are vehicles having computers and control systems that perform driving and navigation tasks conventionally performed by a human driver. As AV technologies continue to advance, they will become increasingly safe and efficient. Where multiple AVs are involved, as in AV fleet deployments, improvements in vehicle operation and safety may increasingly depend on coordination of navigation and sensory tasks between fleet vehicles. As discussed herein, the improvements to AV operations can also be improved using vehicle and driving scenario simulations.

### BRIEF DESCRIPTION OF THE DRAWINGS

Certain features of the subject technology are set forth in the appended claims. However, the accompanying drawings, which are included to provide further understanding, illustrate disclosed aspects and together with the description serve to explain the principles of the subject technology. In the drawings:

FIG. 1 conceptually illustrates a recorded driving scene and its digital-twin, generated from semantic scene data, according to some aspects of the disclosed technology.

FIG. 2 illustrates a conceptual block diagram of an example system for generating a simulated driving scene using semantic data, according to some aspects of the disclosed technology.

FIG. 3 illustrates steps of a process for generating a simulated scene using semantic data, according to some aspects of the disclosed technology.

FIG. 4 illustrates steps of an example process for using a simulated scene to facilitate testing of various AV operations, according to some aspects of the disclosed technology.

FIG. 5 illustrates an example system environment that can be used to facilitate AV dispatch and operations, according to some aspects of the disclosed technology.

FIG. 6 illustrates an example processor-based system with which some aspects of the subject technology can be implemented.

### DETAILED DESCRIPTION

The detailed description set forth below is intended as a description of various configurations of the subject technology but is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

As described herein, one aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

In the course of normal operation, autonomous vehicles (AVs) are sometimes configured to collect and store sensor information corresponding with the environs in which they operate. Depending on the AV configuration, the collected sensor data can include data of various types, including but not limited to: Light Detection and Ranging (LiDAR) data, radar data, sonar data, and/or camera data, and the like. The collected sensor data, when combined with other collected data, such as location/map data, can be combined to form a collection of data (e.g., road data, or road bag data) that can be used to reconstruct real-world driving scenarios encountered by the AV. In some aspects, road data can include sensor data corresponding with various agents or entities that were encountered by the AV. By way of example, agents or entities can include active traffic participants, such as other vehicles, bicycles, and/or driving obstacles, such as road cones or double-parked vehicles, etc.

Road data is sometimes used to re-create or simulate recorded scenarios, for example, on different AV stack versions. However, because the road data includes sensor and map data that is specific to the AV configuration and driving scenarios encountered, the data cannot be extrapolated for use in simulating novel scenes or driving scenarios. Additionally, the format of conventional road data makes it difficult to test vehicle platforms and AV stacks that differ from those used to collect the original road data.

Aspects of the disclosed technology address the foregoing limitations by providing solutions for adapting legacy road data (or road bag data) into a semantic format that preserves the original behaviors and intents of various agents in the recorded scene. By way of example, the semantic data can be used to represent the motion and behavior of various vehicles, and/or pedestrians in a given scene. Additionally, the semantic data can be used to represent interactions between scene agents, such as the deceleration of a trailing vehicle in response to the deceleration of a lead vehicle, or stopping before executing a turn when pedestrians are stopped in a crosswalk area. The semantic data (also: semantic scene data) can then be used to re-create a simulated scene that is identical to, or nearly identical to, the originally recorded scene. As such, the semantic scene can be a digital-twin of the originally recorded scene. Using the semantic scene data, driving scenarios can then be simulated on different AV stack versions, as well as entirely different AV platforms.

Additionally, by converting the road-bag data into a semantic format, the resulting semantic scene data can then be modified (permuted) to create entirely novel simulated driving scenarios. For example, where agent behaviors are changed, and/or agents are altogether added or removed from a scene. The variously resulting novel driving scenarios can then be recorded by capturing virtual/synthetic sensor feeds, e.g., to produce synthetic (virtual) road-bag data that can be used for various AV testing and validation purposes.

Although the instant disclosure encompasses the use of semantic data for creating simulated driving scenarios, it is understood that simulated three-dimensional (3D) environments can be generated using data from various other sources. The generation of simulated environments is discussed in detail in U.S. patent application Ser. No.: 17/125,558, entitled, “PROCEDURALLY GENERATED THREE-DIMENSIONAL ENVIRONMENT FOR USE IN AUTONOMOUS VEHICLE SIMULATIONS,” which is hereby incorporated by reference in its entirety. It is understood that, as used herein, road data (or road-bag data) can include various types of data regarding driving scenarios, such as various types of sensor data, map data, and/or weather data, etc. Depending on the desired implementation, the road data may be stored in various different formats, or in different data structures, without departing from the scope of the disclosed technology.

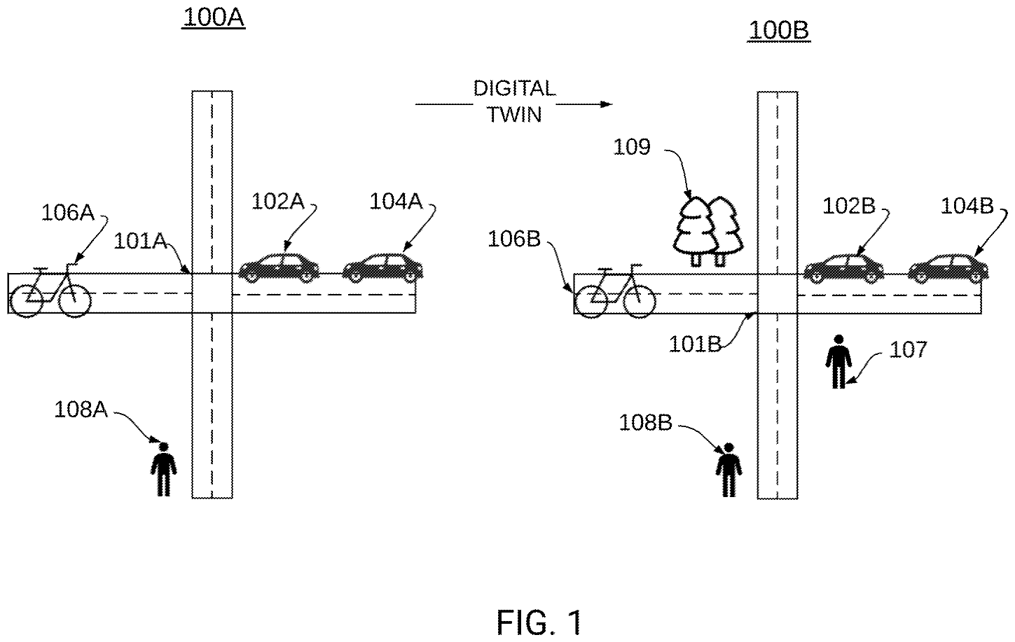

FIG. 1 conceptually illustrates a recorded driving scene 100A, and a corresponding digital-twin 100B of recorded driving scene 100A. In the example of FIG. 1, recorded scene 100A includes a collection of agents operating on a roadway, e.g., vehicles 102A, 104A, a bicyclist 106A, and a pedestrian 108A. It is understood that a greater (or fewer) number of agents or traffic participants may be present in a given driving scene/scenario. Additionally, various other agent types may be present, such as other types of vehicles, traffic participants, and/or pedestrians without departing from the scope of the disclosed technology. As used herein, ‘agent’ may encompass any entity that exhibits motion and/or interactions with any object and/or other entity in a recorded scene. By way of illustrative example, agents can include pedestrians and their attendant behaviors, such as, pedestrians on sidewalks, or in crosswalks, etc.

In practice, scene 100A represents an example of the types of data (e.g., agents, roadways, various traffic participants, etc.) that can be collected and represented in road data. Road data can additionally include temporal information (timestamps), map data, and other types of location/positioning data, including any data that can be measured/captured using various AV sensors, such as, LiDAR/s, radar/s, accelerometer/s, and/or camera/s etc. (not illustrated). In some aspects, road data may include thermal data, for example, collected by one or more thermal imaging devices, and/or acoustic data collected using one or more microphones, etc.

As discussed above, road data can be used to record and store data collected by AVs while in operation, as such the road back data can be used to record driving scenes, for example, from the perspective of the AV collecting the data. As such, road data can be used to reconstruct previously recorded driving scenarios. However, because road data consists of sensor specific data and other situation specific measurements, conventional road data cannot be easily used to construct simulated scenes, for example, that differ from those corresponding with the originally collected road data. To facilitate the generation of entirely new (simulated) driving scenarios (herein: simulated scenes) the road data can be processed into a semantic format (herein: semantic scene data), whereby the behaviors and intentions of various agents in the scene are preserved. By converting road data into a semantic format, the behaviors of scene agents within the simulated environment can be modified/permuted without rendering the scene untenable for simulation purposes. For example, by using a semantic format, simulated scenes can be generated in which the behaviors of various agents are modified, and the behaviors of other interacting agents are automatically modified/updated in a manner that maintains scene coherence. As discussed in further detail below, the simulate scenes may be generated that include additional (or fewer) agents, and/or novel vehicle interaction scenarios.

In the example of FIG. 1, simulated scene 100B represents a simulate scene constructed from semantic scene data, e.g., from the road data corresponding with recorded scene 100A. Simulated scene 100B can include all of the elements/agents for recorded scene 100A, and in this way can function as a digital-twin of recorded scene 100A. By representing the behaviors of various agents in simulated scene 100B with semantic representations, the simulated scene can be used to simulated functions on different AV stack versions, and/or on entirely different AV platforms. By way of example, in recorded scene 100A, vehicle 104A may follow behind vehicle 102A through the intersection 101A. Relationships between vehicle 104A and 102A can be encoded into a semantic format and rendered into semantic scene 100B, whereby digital-twin vehicles 104B, and 102B exhibit the same behavior. However, using the semantic format, behaviors of one or more agents in semantic scene 100B can be modified. For example, the behavior of vehicle 102B may be modified in semantic scene 100B such that the vehicle exhibits different or modified position, velocity, acceleration, and/or jerk parameters.

Additionally, the modified behavioral characteristics can include changes to navigation and/or routing characteristics. Further to the above example, after the vehicle's behavioral characteristics have been modified, the vehicle can slow to a stop, and then make a right-turn at intersection 101B. Using the legacy road-bag data format (i.e., without the benefit of semantic encoding), vehicle 104A may collide with vehicle 102A. However, in semantic scene 100B, wherein a relationship between vehicle 104B and 102B is semantically encoded, the changed behavior of vehicle 102B can induce a corresponding change in behavior of vehicle 104B. For example, vehicle 104B may slow down to maintain a safe distance behind vehicle 102B, and then proceed through intersection 101B (without collision) once a turn has been successfully executed by vehicle 102B.

By encoding the behaviors and behavioral relationships between entities in a given scene, other permutations can also be made. As further illustrated in semantic scene 100B, agents may be added (e.g., pedestrian 107) or removed. Additionally, non-traffic participants, such as trees 109 or other artifacts may be added (or removed from the scene). As discussed in further detail below, semantic scene 100B can be used to test functionalities on AV stacks of different types or versions, and/or to run simulations on entirely different AV platforms, such as new vehicle configurations, for which collected road data does not yet exists.

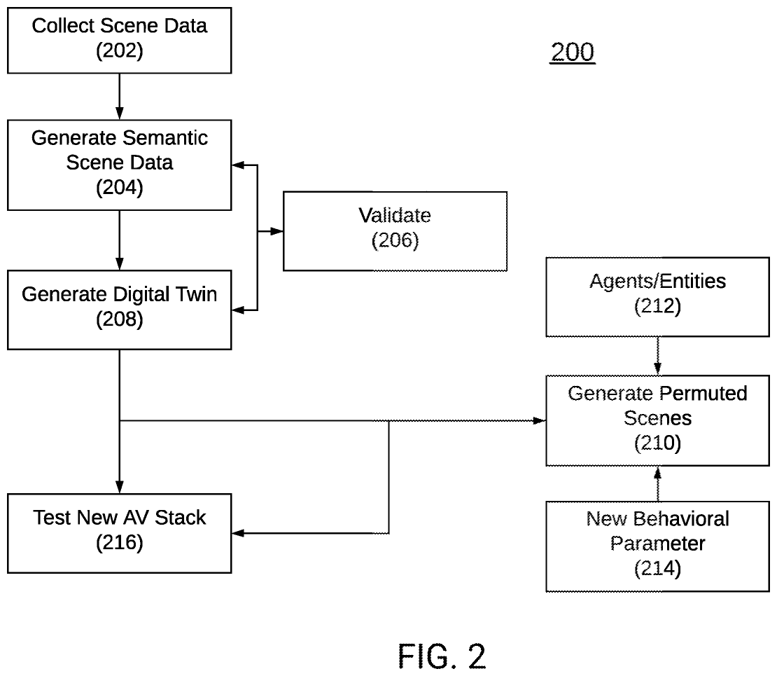

FIG. 2 illustrates a conceptual block diagram of an example system 200 for generating a simulated driving scene using semantic scene data. Initially, real-world scene data (e.g., bag data) is collected (block 202) by system 200. As discussed above, the bag data can be generated in the course of AV operations, including the collection and storing of various forms of raw sensor data. The bag (scene) data is then processed for conversion into a semantic format (block 204).

Processing of bag data to generate semantic scene data can involve several classification and mapping processes. In some aspects, noise is filtered from the bag data, for example, to remove noisy entities and/or orientations. For example, noise can be filtered/removed from the bag data by identifying entities with trajectories and/or vehicle dynamics that are inconsistent with expected on-road behavior, for example, given the corresponding semantic map information. Additionally, agents can be mapped to fixed semantic classifications. By way of example, bag data can be processed to identify agents and classify them based on object type, such as by tagging with fixed semantic labels, e.g., ‘pedestrian,’ bike,“electric vehicle,” bus,' etc. Entities can also be fitted with discrete scene kinematics by tagging them with properties associated with their motion throughout the scene. By way of example, various agents may be fitted with discrete measurements of position, velocity, acceleration, and/or jerk for various frames in the scene.

In some aspects, the resulting semantic scene data is validated, for example, to ensure that semantic scene data adequately represents the recorded scene and does not produce errors (block 206). By way of example, various models, such as a probability of take-over (PTKO) model, may be used to assess the fidelity of a semantic scene. For example, PTKO scores may be calculated for a recorded scene, as well as it's digital-twin (semantic scene representation) to determine of the PTKO scores are substantially similar. Equivalent, or near equivalent scores, may indicate that the semantic scene accurately recreates the agent behaviors from the recorded scene, whereas large PTKO discrepancies may indicate an invalid or error-ridden semantic representation. In other approaches, metrics such as a time-to-collision metric can be computed for the collected scene data, and for the resulting semantic scene data, and if the metrics are similar (or sufficiently similar), then the semantic scene data may be deemed valid. It is understood that other metrics can be used to perform validity checks, without departing from the scope of the disclosed technology.

Irrespective of the validation process, the semantic scene data can be used to generate a digital-twin of the recorded scene (block 208) represented by scene data collected at block 202. As illustrated in the examples of FIG. 1, the digital-twin can include a recreation of driving scenarios from the original road data, or may include modifications to various agents and/or behaviors, for example, to generate a novel (simulated) driving scenario using permuted scenes (block 210). By way of example, different agents (e.g., vehicles, bicyclists, and/or pedestrians, etc.), may be removed from (or inserted into) the simulated (semantic) scene (block 212). Similarly, the behaviors and/or intent of different agents can be modified, e.g., by changing, adding, or removing behavioral parameters (block 214). In some aspects, environmental parameters, such as atmospheric events, speed limits, lighting and/or time of day may be modified to create a permuted simulation based on the originally recorded scene. In this manner, novel driving scenarios and interactions can be simulated and used to inform AV testing. In some instances, the validation process (block 206) can be performed on the generated semantic scenario or digital-twin.

Additionally, in some aspects, the generated semantic scene can be used to test new or different AV stack versions, and/or new or different AV platforms having different hardware or hardware configurations (block 216). By way of example, different sensor configurations can be tested to determine what impact (if any) field of view (FOV) changes have on AV performance. Similarly, newly generated semantic scenes can be used to facilitate testing of different vehicle models, and/or those having different shape characteristics and/or driving characteristics, such as vehicles with different breaking, acceleration, and/or turning behavior, etc.

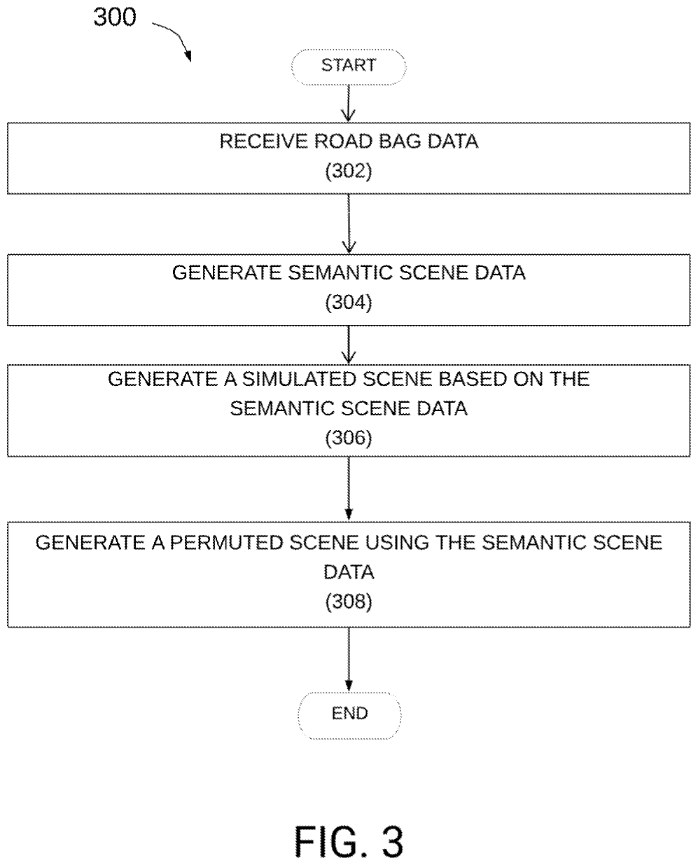

FIG. 3 illustrates steps of a process 300 for generating a simulated scene using semantic data, according to some aspects of the disclosed technology. Process 300 begins with step 302 in which road data is received, for example, by a system configured to generate simulated driving scenes, such as system 200, discussed above. In some aspects, the road data may include raw sensor data. However, in other aspects, the road data may include raw sensor data and some labelling, for example, that includes machine-learning or human generated labels for one or more objects represented in the road data.

At step 304, semantic encoding is performed on the road data, e.g., to generate semantic scene data wherein the agents and behaviors from the road data (or road bag data) are semantically encoded. As discussed above, semantic encoding can also include one or more processing steps for removing/filtering noise from the road data. For example, noise can be removed from the road data by identifying entities with trajectories and/or vehicle dynamics that are inconsistent with expected on-road behavior, for example, given the corresponding semantic map information. The resulting semantic scene may be of a static nature, for example, for use in perception testing. In some aspects, testing of static (single) frames can be useful for comparing the performance of perception between two different sensor configurations. For example, A/B testing can be used to compare entity classifications for different configurations (e.g., configuration A, and configuration B), with respect to a common scene. In other aspects, as discussed above, the semantic scenes can be multi-frame, for example, to represent behaviors by various agents occurring over a given timeframe. In some approaches, multi-frame scenes can be more useful for testing end-to-end AV behavior; for example, multi-frame testing can be helpful in revealing what the AV does differently based on specific scene changes.

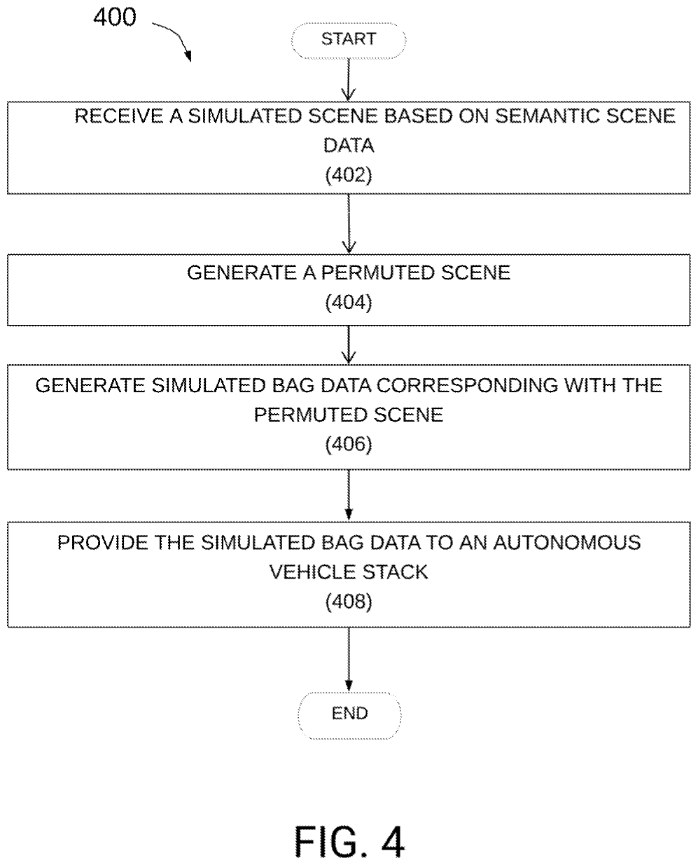

At step 306, one or more permuted scenes are generated using semantic scene data. Permuted scenes can include those representing all permutations or variations of agents and/or behaviors in a given synthetic scene. Additional details regarding how permuted scenes can be used to facilitate the simulation of various AV operations is discussed in further detail with respect to FIG. 4.

FIG. 4 illustrates steps of an example process 400 for using a simulated scene to facilitate the testing of various AV operations. Process 400 begins with step 402 in which a simulated scene is received. As discussed above, the simulated scene can be encoded with semantic scene data representing relationships between various agents or entities (e.g., vehicles, pedestrians and/or other traffic participants) in a simulated environment.

At step 404, a permuted scene is generated based on the semantic scene, for example, by modifying one or more parameters of the simulated scene. In some aspects, a behavior of one or more agents in the scene may be modified. By way of example, parameters for a particular agent (e.g., a vehicle), such as velocity and/or acceleration may be modified to generate the permuted scene. In another example, behaviors may be modified, such as by altering navigation and/or routing behaviors of one or more vehicles in the scene.

At step 406, synthetic road data is generated. The synthetic road data can be generated by collecting sensor data from one or more virtual/simulated AV sensors that are exposed to the permuted scene. By way of example, synthetic LiDAR and/or camera data can be collected in the virtual environment in which the permuted scene (driving scenario) is simulated.

At step 408, the synthetic road data can be provided to an autonomous vehicle (AV) stack, for example, to facilitate testing of one or more AV functions or operations. By way of example, exposing the synthetic road data to an AV stack can help to perform testing and/or training to improve routing, maneuvering, and/or navigation functions.

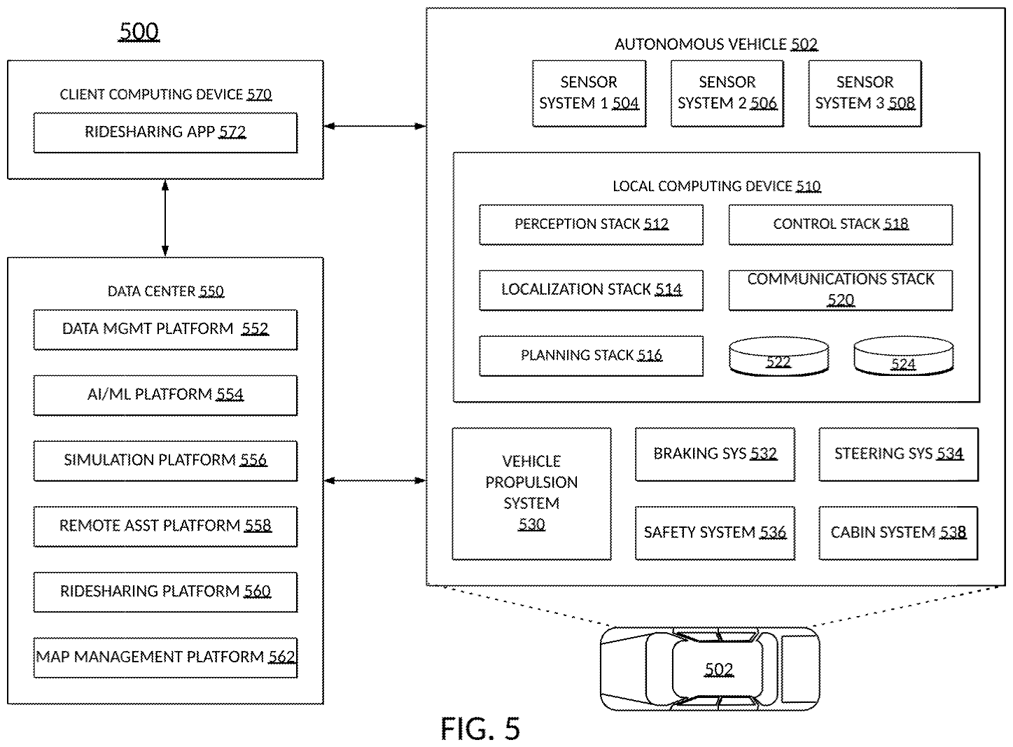

Turning now to FIG. 5 illustrates an example of an AV management system 500. One of ordinary skill in the art will understand that, for the AV management system 500 and any system discussed in the present disclosure, there can be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 500 includes an AV 502, a data center 550, and a client computing device 570. The AV 502, the data center 550, and the client computing device 570 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 502 can navigate about roadways without a human driver based on sensor signals generated by multiple sensor systems 504, 506, and 508. The sensor systems 504-508 can include different types of sensors and can be arranged about the AV 502. For instance, the sensor systems 504-508 can comprise Inertial Measurement Units (IMUs), cameras (e.g., still image cameras, video cameras, etc.), light sensors (e.g., LIDAR systems, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 504 can be a camera system, the sensor system 506 can be a LIDAR system, and the sensor system 508 can be a RADAR system. Other embodiments may include any other number and type of sensors.

AV 502 can also include several mechanical systems that can be used to maneuver or operate AV 502. For instance, the mechanical systems can include vehicle propulsion system 530, braking system 532, steering system 534, safety system 536, and cabin system 538, among other systems. Vehicle propulsion system 530 can include an electric motor, an internal combustion engine, or both. The braking system 532 can include an engine brake, brake pads, actuators, and/or any other suitable componentry configured to assist in decelerating AV 502. The steering system 534 can include suitable componentry configured to control the direction of movement of the AV 502 during navigation. Safety system 536 can include lights and signal indicators, a parking brake, airbags, and so forth. The cabin system 538 can include cabin temperature control systems, in-cabin entertainment systems, and so forth. In some embodiments, the AV 502 may not include human driver actuators (e.g., steering wheel, handbrake, foot brake pedal, foot accelerator pedal, turn signal lever, window wipers, etc.) for controlling the AV 502. Instead, the cabin system 538 can include one or more client interfaces (e.g., Graphical User Interfaces (GUIs), Voice User Interfaces (VUIs), etc.) for controlling certain aspects of the mechanical systems 530-538.

AV 502 can additionally include a local computing device 510 that is in communication with the sensor systems 504-508, the mechanical systems 530-538, the data center 550, and the client computing device 570, among other systems. The local computing device 510 can include one or more processors and memory, including instructions that can be executed by the one or more processors. The instructions can make up one or more software stacks or components responsible for controlling the AV 502; communicating with the data center 550, the client computing device 570, and other systems; receiving inputs from riders, passengers, and other entities within the AV's environment; logging metrics collected by the sensor systems 504-508; and so forth. In this example, the local computing device 510 includes a perception stack 512, a mapping and localization stack 514, a planning stack 516, a control stack 518, a communications stack 520, an HD geospatial database 522, and an AV operational database 524, among other stacks and systems.

Perception stack 512 can enable the AV 502 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 504-508, the mapping and localization stack 514, the HD geospatial database 522, other components of the AV, and other data sources (e.g., the data center 550, the client computing device 570, third-party data sources, etc.). The perception stack 512 can detect and classify objects and determine their current and predicted locations, speeds, directions, and the like. In addition, the perception stack 512 can determine the free space around the AV 502 (e.g., to maintain a safe distance from other objects, change lanes, park the AV, etc.). The perception stack 512 can also identify environmental uncertainties, such as where to look for moving objects, flag areas that may be obscured or blocked from view, and so forth.

Mapping and localization stack 514 can determine the AV's position and orientation (pose) using different methods from multiple systems (e.g., GPS, IMUs, cameras, LIDAR, RADAR, ultrasonic sensors, the HD geospatial database 522, etc.). For example, in some embodiments, the AV 502 can compare sensor data captured in real-time by the sensor systems 504-508 to data in the HD geospatial database 522 to determine its precise (e.g., accurate to the order of a few centimeters or less) position and orientation. The AV 502 can focus its search based on sensor data from one or more first sensor systems (e.g., GPS) by matching sensor data from one or more second sensor systems (e.g., LIDAR). If the mapping and localization information from one system is unavailable, the AV 502 can use mapping and localization information from a redundant system and/or from remote data sources.

The planning stack 516 can determine how to maneuver or operate the AV 502 safely and efficiently in its environment. For example, the planning stack 516 can receive the location, speed, and direction of the AV 502, geospatial data, data regarding objects sharing the road with the AV 502 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 502 from one point to another. The planning stack 516 can determine multiple sets of one or more mechanical operations that the AV 502 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 516 can select from multiple backup plans to carry out. For example, while preparing to change lanes to turn right at an intersection, another vehicle may aggressively cut into the destination lane, making the lane change unsafe. The planning stack 516 could have already determined an alternative plan for such an event, and upon its occurrence, help to direct the AV 502 to go around the block instead of blocking a current lane while waiting for an opening to change lanes.

The control stack 518 can manage the operation of the vehicle propulsion system 530, the braking system 532, the steering system 534, the safety system 536, and the cabin system 538. The control stack 518 can receive sensor signals from the sensor systems 504-508 as well as communicate with other stacks or components of the local computing device 510 or a remote system (e.g., the data center 550) to effectuate operation of the AV 502. For example, the control stack 518 can implement the final path or actions from the multiple paths or actions provided by the planning stack 516. This can involve turning the routes and decisions from the planning stack 516 into commands for the actuators that control the AV's steering, throttle, brake, and drive unit.

The communication stack 520 can transmit and receive signals between the various stacks and other components of the AV 502 and between the AV 502, the data center 550, the client computing device 570, and other remote systems. The communication stack 520 can enable the local computing device 510 to exchange information remotely over a network, such as through an antenna array or interface that can provide a metropolitan WIFI network connection, a mobile or cellular network connection (e.g., Third Generation (3G), Fourth Generation (5G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communication stack 520 can also facilitate local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 522 can store HD maps and related data of the streets upon which the AV 502 travels. In some embodiments, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal U-turn lanes; permissive or protected only right turn lanes; etc.). The traffic controls lane can include geospatial information of traffic signal lights, traffic signs, and other road objects and related attributes.

The AV operational database 524 can store raw AV data generated by the sensor systems 504-508 and other components of the AV 502 and/or data received by the AV 502 from remote systems (e.g., the data center 550, the client computing device 570, etc.). In some embodiments, the raw AV data can include HD LIDAR point cloud data, image data, RADAR data, GPS data, and other sensor data that the data center 550 can use for creating or updating AV geospatial data as discussed further below with respect to FIG. 2 and elsewhere in the present disclosure.

The data center 550 can be a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and so forth. The data center 550 can include one or more computing devices remote to the local computing device 510 for managing a fleet of AVs and AV-related services. For example, in addition to managing the AV 502, the data center 550 may also support a ridesharing service, a delivery service, a remote/roadside assistance service, street services (e.g., street mapping, street patrol, street cleaning, street metering, parking reservation, etc.), and the like.

The data center 550 can send and receive various signals to and from the AV 502 and client computing device 570. These signals can include sensor data captured by the sensor systems 504-508, roadside assistance requests, software updates, ridesharing pick-up and drop-off instructions, and so forth. In this example, the data center 550 includes a data management platform 552, an Artificial Intelligence/Machine Learning (AI/ML) platform 554, a simulation platform 556, a remote assistance platform 558, a ridesharing platform 560, and map management system platform 562, among other systems.

Data management platform 552 can be a “big data” system capable of receiving and transmitting data at high velocities (e.g., near real-time or real-time), processing a large variety of data, and storing large volumes of data (e.g., terabytes, petabytes, or more of data). The varieties of data can include data having different structure (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 550 can access data stored by the data management platform 552 to provide their respective services.

The AI/ML platform 554 can provide the infrastructure for training and evaluating machine learning algorithms for operating the AV 502, the simulation platform 556, the remote assistance platform 558, the ridesharing platform 560, the map management system platform 562, and other platforms and systems. Using the AI/ML platform 554, data scientists can prepare data sets from the data management platform 552; select, design, and train machine learning models; evaluate, refine, and deploy the models; maintain, monitor, and retrain the models; and so on.

The simulation platform 556 can enable testing and validation of the algorithms, machine learning models, neural networks, and other development efforts for the AV 502, the remote assistance platform 558, the ridesharing platform 560, the map management system platform 562, and other platforms and systems. The simulation platform 556 can replicate a variety of driving environments and/or reproduce real-world scenarios from data captured by the AV 502, including rendering geospatial information and road infrastructure (e.g., streets, lanes, crosswalks, traffic lights, stop signs, etc.) obtained from the map management system platform 562; modeling the behavior of other vehicles, bicycles, pedestrians, and other dynamic elements; simulating inclement weather conditions, different traffic scenarios; and so on.

The remote assistance platform 558 can generate and transmit instructions regarding the operation of the AV 502. For example, in response to an output of the AI/ML platform 554 or other system of the data center 550, the remote assistance platform 558 can prepare instructions for one or more stacks or other components of the AV 502.

The ridesharing platform 560 can interact with a customer of a ridesharing service via a ridesharing application 572 executing on the client computing device 570. The client computing device 570 can be any type of computing system, including a server, desktop computer, laptop, tablet, smartphone, smart wearable device (e.g., smart watch, smart eyeglasses or other Head-Mounted Display (HMD), smart ear pods or other smart in-ear, on-ear, or over-ear device, etc.), gaming system, or other general purpose computing device for accessing the ridesharing application 572. The client computing device 570 can be a customer's mobile computing device or a computing device integrated with the AV 502 (e.g., the local computing device 510). The ridesharing platform 560 can receive requests to be picked up or dropped off from the ridesharing application 572 and dispatch the AV 502 for the trip.

Map management system platform 562 can provide a set of tools for the manipulation and management of geographic and spatial (geospatial) and related attribute data. The data management platform 552 can receive LIDAR point cloud data, image data (e.g., still image, video, etc.), RADAR data, GPS data, and other sensor data (e.g., raw data) from one or more AVs 502, UAVs, satellites, third-party mapping services, and other sources of geospatially referenced data. The raw data can be processed, and map management system platform 562 can render base representations (e.g., tiles (2D), bounding volumes (3D), etc.) of the AV geospatial data to enable users to view, query, label, edit, and otherwise interact with the data. Map management system platform 562 can manage workflows and tasks for operating on the AV geospatial data. Map management system platform 562 can control access to the AV geospatial data, including granting or limiting access to the AV geospatial data based on user-based, role-based, group-based, task-based, and other attribute-based access control mechanisms. Map management system platform 562 can provide version control for the AV geospatial data, such as to track specific changes that (human or machine) map editors have made to the data and to revert changes when necessary. Map management system platform 562 can administer release management of the AV geospatial data, including distributing suitable iterations of the data to different users, computing devices, AVs, and other consumers of HD maps. Map management system platform 562 can provide analytics regarding the AV geospatial data and related data, such as to generate insights relating to the throughput and quality of mapping tasks.

In some embodiments, the map viewing services of map management system platform 562 can be modularized and deployed as part of one or more of the platforms and systems of the data center 550. For example, the AI/ML platform 554 may incorporate the map viewing services for visualizing the effectiveness of various object detection or object classification models, the simulation platform 556 may incorporate the map viewing services for recreating and visualizing certain driving scenarios, the remote assistance platform 558 may incorporate the map viewing services for replaying traffic incidents to facilitate and coordinate aid, the ridesharing platform 560 may incorporate the map viewing services into the client application 572 to enable passengers to view the AV 502 in transit en route to a pick-up or drop-off location, and so on.

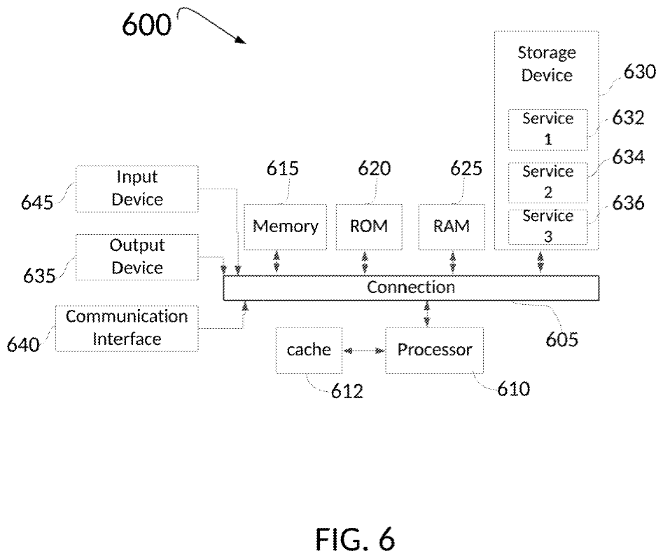

FIG. 6 illustrates an example processor-based system with which some aspects of the subject technology can be implemented. For example, processor-based system 600 can be any computing device making up internal computing system 610, remote computing system 650, a passenger device executing the rideshare app 670, internal computing device 630, or any component thereof in which the components of the system are in communication with each other using connection 605. Connection 605 can be a physical connection via a bus, or a direct connection into processor 610, such as in a chipset architecture. Connection 605 can also be a virtual connection, networked connection, or logical connection.

In some embodiments, computing system 600 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 600 includes at least one processing unit (CPU or processor) 510 and connection 605 that couples various system components including system memory 615, such as read-only memory (ROM) 620 and random-access memory (RAM) 625 to processor 610. Computing system 600 can include a cache of high-speed memory 612 connected directly with, in close proximity to, or integrated as part of processor 610.

Processor 610 can include any general-purpose processor and a hardware service or software service, such as services 632, 634, and 636 stored in storage device 630, configured to control processor 610 as well as a special-purpose processor where software instructions are incorporated into the actual processor design. Processor 610 may essentially be a completely self-contained computing system, containing multiple cores or processors, a bus, memory controller, cache, etc. A multi-core processor may be symmetric or asymmetric.

To enable user interaction, computing system 600 includes an input device 645, which can represent any number of input mechanisms, such as a microphone for speech, a touch-sensitive screen for gesture or graphical input, keyboard, mouse, motion input, speech, etc. Computing system 600 can also include output device 635, which can be one or more of a number of output mechanisms known to those of skill in the art. In some instances, multimodal systems can enable a user to provide multiple types of input/output to communicate with computing system 600. Computing system 600 can include communications interface 640, which can generally govern and manage the user input and system output. The communication interface may perform or facilitate receipt and/or transmission wired or wireless communications via wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

Communication interface 640 may also include one or more Global Navigation Satellite System (GNSS) receivers or transceivers that are used to determine a location of the computing system 600 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 630 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (L1/L2/L3/L4/L5/L#), resistive random-access memory (RRAM/ReRAM), phase change memory (PCM), spin transfer torque RAM (STT-RAM), another memory chip or cartridge, and/or a combination thereof.

Storage device 630 can include software services, servers, services, etc., that when the code that defines such software is executed by the processor 610, it causes the system to perform a function. In some embodiments, a hardware service that performs a particular function can include the software component stored in a computer-readable medium in connection with the necessary hardware components, such as processor 610, connection 605, output device 635, etc., to carry out the function.

As understood by those of skill in the art, machine-learning based classification techniques can vary depending on the desired implementation. For example, machine-learning classification schemes can utilize one or more of the following, alone or in combination: hidden Markov models; recurrent neural networks; convolutional neural networks (CNNs); deep learning; Bayesian symbolic methods; general adversarial networks (GANs); support vector machines; image registration methods; applicable rule-based system. Where regression algorithms are used, they may include including but are not limited to: a Stochastic Gradient Descent Regressor, and/or a Passive Aggressive Regressor, etc.

Machine learning classification models can also be based on clustering algorithms (e.g., a Mini-batch K-means clustering algorithm), a recommendation algorithm (e.g., a Miniwise Hashing algorithm, or Euclidean Locality-Sensitive Hashing (LSH) algorithm), and/or an anomaly detection algorithm, such as a Local outlier factor. Additionally, machine-learning models can employ a dimensionality reduction approach, such as, one or more of: a Mini-batch Dictionary Learning algorithm, an Incremental Principal Component Analysis (PCA) algorithm, a Latent Dirichlet Allocation algorithm, and/or a Mini-batch K-means algorithm, etc.

Embodiments within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure. Claim language reciting “at least one of” a set indicates that one member of the set or multiple members of the set satisfy the claim.

Aspect 1: a system comprising: one or more processors; and a computer-readable medium coupled to the one or more processors, wherein the computer-readable medium comprises instructions that are configured to cause the one or more processors to perform operations comprising: receiving road data, wherein the road data comprises sensor data collected for a recorded scene measured using one or more vehicle-mounted sensors; processing the road data to generate semantic scene data, wherein the semantic scene data comprises behavioral representations of one or more agents identified by the sensor data; and generating a simulated scene based on the semantic scene data, wherein the simulated scene is a digital twin of the recorded scene measured using the one or more vehicle-mounted sensors.

Aspect 2: the system of aspect 1, wherein the processors are further configured to perform operations comprising: generating a permuted scene by modifying one or more parameters associated with one or more agents in the simulated scene.

Aspect 3: the system of aspects 1-2, wherein the processors are further configured to perform operations comprising: generating a permuted scene by adding or removing one or more agents in the simulated scene.

Aspect 4: the system of aspects 1-3, wherein the sensor data comprises one or more of: Light Detection and Ranging (LiDAR) data, or camera data.

Aspect 5: system of aspects 1-4, wherein the sensor data collected for the recorded scene is associated with a first autonomous vehicle (AV) stack, and wherein the simulated scene is configured to facilitate testing using a second AV stack, and wherein the first AV stack is different from the second AV stack.

Aspect 6: the system of aspects 1-5, wherein the one or more agents comprises one or more of: a vehicle, a bicycle, or a pedestrian.

Aspect 7: the system of aspects 1-6, wherein the behavioral representations of the one or more agents comprises indications of one or more of: vehicle turns, vehicle stops, or a vehicle velocity.

Aspect 8: a computer-implemented method, comprising: receiving road data, wherein the road data comprises sensor data collected for a recorded scene measured using one or more vehicle-mounted sensors; processing the road data to generate semantic scene data, wherein the semantic scene data comprises behavioral representations of one or more agents identified by the sensor data; and generating a simulated scene based on the semantic scene data, wherein the simulated scene is a digital twin of the recorded scene measured using the one or more vehicle-mounted sensors.

Aspect 9: the method of aspect 8, further comprising: generating a permuted scene by modifying one or more parameters associated with one or more agents in the simulated scene.

Aspect 10: the method of aspects 8-9, further comprising: generating a permuted scene by adding or removing one or more agents in the simulated scene.

Aspect 11: the method of aspects 8-10, wherein the sensor data comprises one or more of: Light Detection and Ranging (LiDAR) data, or camera data.

Aspect 12: the method of aspects 8-11, wherein the sensor data collected for the recorded scene is associated with a first autonomous vehicle (AV) stack, and wherein the simulated scene is configured to facilitate testing using a second AV stack, and wherein the first AV stack is different from the second AV stack.

Aspect 13: the method of aspects 8-12, wherein the one or more agents comprises one or more of: a vehicle, a bicycle, or a pedestrian.

Aspect 14: the method of aspects 8-13, wherein the behavioral representations of the one or more agents comprises indications of one or more of: vehicle turns, vehicle stops, or a vehicle velocity.

Aspect 15: a non-transitory computer-readable storage medium comprising instructions stored therein, which when executed by one or more processors, cause the processors to perform operations comprising: receiving road data, wherein the road data comprises sensor data collected for a recorded scene measured using one or more vehicle-mounted sensors; processing the road data to generate semantic scene data, wherein the semantic scene data comprises behavioral representations of one or more agents identified by the sensor data; and generating a simulated scene based on the semantic scene data, wherein the simulated scene is a digital twin of the recorded scene measured using the one or more vehicle-mounted sensors.

Aspect 16: The non-transitory computer-readable storage medium of aspect 15, wherein the instructions are further configured to cause the processors to perform operations comprising: generating a permuted scene by modifying one or more parameters associated with one or more agents in the simulated scene.

Aspect 17: the non-transitory computer-readable storage medium of aspects 15-16, wherein the instructions are further configured to cause the processors to perform operations comprising: generating a permuted scene by adding or removing one or more agents in the simulated scene.

Aspect 18: the non-transitory computer-readable storage medium of aspects 15-17, wherein the sensor data comprises one or more of: Light Detection and Ranging (LiDAR) data, or camera data.

Aspect 19: the non-transitory computer-readable storage medium of aspects 15-18, wherein the sensor data collected for the recorded scene is associated with a first autonomous vehicle (AV) stack, and wherein the simulated scene is configured to facilitate testing using a second AV stack, and wherein the first AV stack is different from the second AV stack.

Aspect 20 the non-transitory computer-readable storage medium of aspects 15-19, wherein the one or more agents comprises one or more of: a vehicle, a bicycle, or a pedestrian.

Aspect 21: a system comprising: one or more processors; and a computer-readable medium coupled to the one or more processors, wherein the computer-readable medium comprises instructions that are configured to cause the one or more processors to perform operations comprising: receiving a simulated scene based on semantic scene data; modifying the simulated scene to generate a permuted scene; generating synthetic bag data corresponding with the permuted scene; and providing the synthetic bag data to an autonomous vehicle (AV) stack.

Aspect 22: the system of aspect 21, wherein modifying the simulated scene to generate the permuted scene, further comprises: modifying a behavior of one or more agents in the simulated scene.

Aspect 23: the system of aspects 21-22, wherein modifying the simulated scene to generate the permuted scene, further comprises: adding one or more agents to the simulated scene.

Aspect 24: the system of aspects 21-23, wherein generating the synthetic bag data corresponding with the permuted scene, further comprises: simulating operation of one or more LiDAR sensor in the permuted scene.

Aspect 25: the system of aspects 21-24, wherein generating the synthetic bag data corresponding with the permuted scene, further comprises: simulating operation of one or more cameras in the permuted scene.

Aspect 26: the system of aspects 21-25, wherein providing the synthetic bag data to the AV stack further comprises: simulating one or more AV routing operations on the AV stack.

Aspect 27: the system of aspects 21-26, wherein providing the synthetic bag data to the AV stack further comprises: simulating one or more AV maneuvering operations on the AV stack.

Aspect 28: a computer-implemented method, comprising: receiving a simulated scene based on semantic scene data; modifying the simulated scene to generate a permuted scene; generating synthetic bag data corresponding with the permuted scene; and providing the synthetic bag data to an autonomous vehicle (AV) stack.

Aspect 29: The method of aspect 28, wherein modifying the simulated scene to generate the permuted scene, further comprises: modifying a behavior of one or more agents in the simulated scene.

Aspect 30: the method of aspects 28-29, wherein modifying the simulated scene to generate the permuted scene, further comprises: adding one or more agents to the simulated scene.

Aspect 31: the method of aspects 28-30, wherein generating the synthetic bag data corresponding with the permuted scene, further comprises: simulating operation of one or more LiDAR sensor in the permuted scene.

Aspect 32: the method of aspects 28-31, wherein generating the synthetic bag data corresponding with the permuted scene, further comprises: simulating operation of one or more cameras in the permuted scene.

Aspect 33: the method of aspects 28-32, wherein providing the synthetic bag data to the AV stack further comprises: simulating one or more AV routing operations on the AV stack.

Aspect 34: the method of aspects 28-33, wherein providing the synthetic bag data to the AV stack further comprises: simulating one or more AV maneuvering operations on the AV stack.

Aspect 35: a non-transitory computer-readable storage medium comprising instructions stored therein, which when executed by one or more processors, cause the processors to perform operations comprising: receiving a simulated scene based on semantic scene data; modifying the simulated scene to generate a permuted scene; generating synthetic bag data corresponding with the permuted scene; and providing the synthetic bag data to an autonomous vehicle (AV) stack.

Aspect 36: the non-transitory computer-readable storage medium of aspect 35, wherein modifying the simulated scene to generate the permuted scene, further comprises: modifying a behavior of one or more agents in the simulated scene.

Aspect 37: the non-transitory computer-readable storage medium of aspects 35-36, wherein modifying the simulated scene to generate the permuted scene, further comprises: adding one or more agents to the simulated scene.

Aspect 38: the non-transitory computer-readable storage medium of aspects 35-37, wherein generating the synthetic bag data corresponding with the permuted scene, further comprises: simulating operation of one or more LiDAR sensor in the permuted scene.

Aspect 39: the non-transitory computer-readable storage medium of aspects 35-38, wherein generating the synthetic bag data corresponding with the permuted scene, further comprises: simulating operation of one or more cameras in the permuted scene.

Aspect 40: the non-transitory computer-readable storage medium of aspects 35-39, wherein providing the synthetic bag data to the AV stack further comprises: simulating one or more AV routing operations on the AV stack.

What is claimed is:

1. A system comprising:
one or more processors; and
a computer-readable medium coupled to the one or more processors, wherein the computer-readable medium comprises instructions that are configured to cause the one or more processors to perform operations comprising:
receiving road data, wherein the road data comprises sensor data collected for a recorded scene measured using one or more vehicle-mounted sensors;
processing the road data to generate semantic scene data, wherein the semantic scene data comprises behavioral representations of one or more agents identified by the sensor data; and
generating a simulated scene based on the semantic scene data, wherein the simulated scene is a digital twin of the recorded scene measured using the one or more vehicle-mounted sensors.

2. The system of claim 1, wherein the processors are further configured to perform operations comprising:
generating a permuted scene by modifying one or more parameters associated with one or more agents in the simulated scene.

3. The system of claim 1, wherein the processors are further configured to perform operations comprising:
generating a permuted scene by adding or removing one or more agents in the simulated scene.

4. The system of claim 1, wherein the sensor data comprises one or more of: Light Detection and Ranging (LiDAR) data, or camera data.

5. The system of claim 1, wherein the sensor data collected for the recorded scene is associated with a first autonomous vehicle (AV) stack, and wherein the simulated scene is configured to facilitate testing using a second AV stack, and wherein the first AV stack is different from the second AV stack.

6. The system of claim 1, wherein the one or more agents comprises one or more of: a vehicle, a bicycle, or a pedestrian.

7. The system of claim 1, wherein the behavioral representations of the one or more agents comprises indications of one or more of: vehicle turns, vehicle stops, or a vehicle velocity.

8. A computer-implemented method, comprising:
receiving road data, wherein the road data comprises sensor data collected for a recorded scene measured using one or more vehicle-mounted sensors;
processing the road data to generate semantic scene data, wherein the semantic scene data comprises behavioral representations of one or more agents identified by the sensor data; and
generating a simulated scene based on the semantic scene data, wherein the simulated scene is a digital twin of the recorded scene measured using the one or more vehicle-mounted sensors.

9. The method of claim 8, further comprising:
generating a permuted scene by modifying one or more parameters associated with one or more agents in the simulated scene.

10. The method of claim 8, further comprising:
generating a permuted scene by adding or removing one or more agents in the simulated scene.

11. The method of claim 8, wherein the sensor data comprises one or more of: Light Detection and Ranging (LiDAR) data, or camera data.

12. The method of claim 8, wherein the sensor data collected for the recorded scene is associated with a first autonomous vehicle (AV) stack, and wherein the simulated scene is configured to facilitate testing using a second AV stack, and wherein the first AV stack is different from the second AV stack.

13. The method of claim 8, wherein the one or more agents comprises one or more of: a vehicle, a bicycle, or a pedestrian.

14. The method of claim 8, wherein the behavioral representations of the one or more agents comprises indications of one or more of: vehicle turns, vehicle stops, or a vehicle velocity.

15. A non-transitory computer-readable storage medium comprising instructions stored therein, which when executed by one or more processors, cause the processors to perform operations comprising:
receiving road data, wherein the road data comprises sensor data collected for a recorded scene measured using one or more vehicle-mounted sensors;
processing the road data to generate semantic scene data, wherein the semantic scene data comprises behavioral representations of one or more agents identified by the sensor data; and
generating a simulated scene based on the semantic scene data, wherein the simulated scene is a digital twin of the recorded scene measured using the one or more vehicle-mounted sensors.

16. The non-transitory computer-readable storage medium of claim 15, wherein the instructions are further configured to cause the processors to perform operations comprising:
generating a permuted scene by modifying one or more parameters associated with one or more agents in the simulated scene.

17. The non-transitory computer-readable storage medium of claim 15, wherein the instructions are further configured to cause the processors to perform operations comprising:
generating a permuted scene by adding or removing one or more agents in the simulated scene.

18. The non-transitory computer-readable storage medium of claim 15, wherein the sensor data comprises one or more of: Light Detection and Ranging (LiDAR) data, or camera data.

19. The non-transitory computer-readable storage medium of claim 15, wherein the sensor data collected for the recorded scene is associated with a first autonomous vehicle (AV) stack, and wherein the simulated scene is configured to facilitate testing using a second AV stack, and wherein the first AV stack is different from the second AV stack.

20. The non-transitory computer-readable storage medium of claim 15, wherein the one or more agents comprises one or more of: a vehicle, a bicycle, or a pedestrian.
